(19) United States
(12) Patent Application Publication
(10) Pub. No.: US 2008/0102643 A1
(43) Pub. Date: May 1, 2008

(54) PATTERNING METHOD

(75) Inventors: Yi-Hsing Chen, Changhua County (TW); Meng-Jun Wang, Taichung County (TW); Jiunn-Hsiung Liao, Tainan County (TW); Min-Chieh Yang, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICROELECTRONICS CORP., Hsinchu City (TW)

(21) Appl. No.: 11/554,600

(22) Filed: Oct. 31, 2006

(51) Int. Cl. H01L 21/302; H01L 21/461

(52) U.S. Cl. 438/710; 438/719; 438/725

(57) ABSTRACT

A patterning method is provided. The method includes the steps of firstly forming an underlying layer, a silicon rich organic layer, and a photoresist layer on the material layer in succession. The photoresist layer is patterned, and the silicon rich organic layer is etched using the photoresist layer as a mask. Then, an etching process is performed to pattern the underlying layer using the silicon rich organic layer as a mask. Reactive gases adopted in the etching process include a passivation gas, an etching gas, and a carrier gas. The passivation gas forms a passivation layer at side walls of the patterned underlying layer during the etching process. After that, the material layer is etched using the underlying layer as a mask to form an opening in material layer. Finally, the underlying layer is removed.

### BACKGROUND OF THE INVENTION

1. Field of the Invention

The present invention relates to a method of manufacturing semiconductors, and more particularly, to a patterning method.

2. Description of Related Art

In the process of manufacturing semiconductors, patterns are generally formed in a photoresist layer through photolithographic processing. The photoresist layer is then employed as an etching mask to perform a dry etching process or a wet etching process, so that the patterns in the photoresist layer are transferred to the to-be-patterned layer thereunder. With the development towards high integration of semiconductor devices, the critical dimensions (CD) of integrated circuits are gradually reduced, and the resolution required by photolithographic processing is correspondingly increased. To meet the requirement of high resolution, the thickness of the photoresist layer is thinned down. However, insufficient thickness of the photoresist layer as an etching mask is very likely to result in the thorough consumption thereof during the process of etching the underlying to-be-patterned layer, so that the desired patterning function cannot be accomplished.

In the prior art, a patterning method adopting a thin photoresist layer is already provided. The method includes the steps of forming a plurality of thin film layers between the thin photoresist layer and the to-be-patterned layer, and thereby the patterning function can be realized through repeatedly transferring the patterns from layers to layers. However, during the process of transferring patterns, the problems of critical dimensions loss (CD loss) and tilt patterns may occur, which leads to the CD bias. Additionally, since the critical dimensions (CD) required by a sparsely patterned region substantially differs from that by a densely patterned region, a so-called “loading effect” is then generated.

In order to moderate the discrepancy of the dimensions, the patterns in the photoresist layer are enlarged as provided in the prior art, so that the CD loss and said discrepancy arisen from the slant pattern are compensated by positively changing the dimensions. Nevertheless, given that the neighboring patterns are too close to each other, the design rule is very likely to be violated, or the bridging problems may easily occur, so that the CD bias cannot be repaired. Hence, the CD biases among a plurality of pattern transferring layers become an imminent issue to be solved.

### SUMMARY OF THE INVENTION

An object of the present invention is to provide a patterning method to diminish the loading effect.

Another object of the present invention is to provide a patterning method to reduce the CD loss.

Still another object of the present invention is to provide a patterning method to modify the tilt patterns.

The present invention provides a patterning method. The method includes the steps of firstly forming an underlying layer, a silicon rich organic layer, and a photoresist layer on a material layer in succession. Next, the photoresist layer is patterned, and the silicon rich organic layer is pattern using the photoresist layer serving as a mask. Thereafter, using said photoresist layer and said silicon rich organic layer as masks, an etching process is perform to patterning the underlying layer. A reactive gas adopted in the etching process includes a passivation gas, an etching gas, and a carrier gas. Afterwards, using said silicon rich organic layer and said underlying layer as masks, an etching process is performed to form an opening in the material layer. Finally, the underlying layer is removed.

According to one embodiment of the present invention, said passivation gas is, for example, SO₂ or SiCl₄, the content of said passivation gas is 0.5%˜60% of the total amount of the reactive gas. When the passivation gas is SO₂, the content of SO₂ is 30%˜60% of the total amount of the reactive gas. In addition, when the passivation gas is SiCl₄, the content of SiCl₄ is 0.5%˜2% of the total amount of the reactive gas. The etching gas is selected from a group consisting of O₂, NF₃, fluorinated hydrocarbon compound, and the combination thereof. The fluorinated hydrocarbon compound is selected from a group consisting of CF₄, CHF₃, CH₂F₂, CH₃F, and the combination thereof. The carrier gas is selected from a group consisting of He, Ar, N₂, and the combination thereof.

According to one embodiment of the present invention, the silicon rich organic layer is, for example, made of organic silicon polymer containing 5-30 wt. % of silicon. The material of the underlying layer includes a novolak resin, for example, an I-line photoresist layer.

According to one embodiment of the present invention, said patterning method further includes performing a trimming process after patterning the photoresist layer and before patterning the silicon rich organic layer. Thereby, the pattern in the photoresist layer is changed.

According to one embodiment of the present invention, said patterning method includes achieving an exposure through an immersion lithography process. The photoresist layer is a waterproof photoresist layer, or a photoresist material layer covered by a waterproof layer.

According to one embodiment of the present invention, said patterning method can be adopted to form a contact opening, a via opening, and/or a trench, wherein the material layer is a dielectric layer, and the opening formed thereby is a contact opening, a via opening, and/or a trench.

According to one embodiment of the present invention, said patterning method can be adopted to form a gate structure, wherein the material layer is successively composed of a gate dielectric layer, a gate conductive layer, and a mask layer from the bottom to the top, and the opening formed therein is a space within the gate structure.

According to one embodiment of the present invention, said patterning method is adopted to form a shallow trench isolation (STI) structure, wherein the material layer is composed of a substrate and a mask layer from the bottom to the top, and the opening formed therein is a trench. After the opening is formed in the material layer, an insulating layer is then formed in the opening. Finally, the mask layer is removed.

The patterning method of the present invention can reduce the CD loss, modifies the tilt patterns, and diminishes the isolate dense loading effect.

In order to the make aforementioned and other objects, features and advantages of the present invention comprehensible, a preferred embodiment accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1E are schematic cross-sectional views illustrating a patterning method according to one embodiment of the present invention.

FIGS. 2A to 2E are schematic cross-sectional views illustrating the steps of fabricating a gate structure according to another embodiment of the present invention.

FIGS. 3A to 3G are schematic cross-sectional views illustrating the steps of fabricating a shallow trench isolation (STI) structure according to still another embodiment of this invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

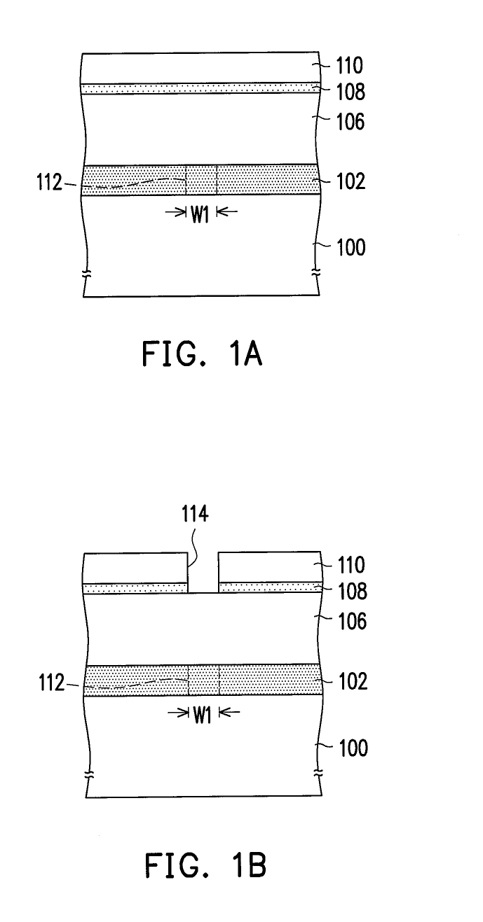

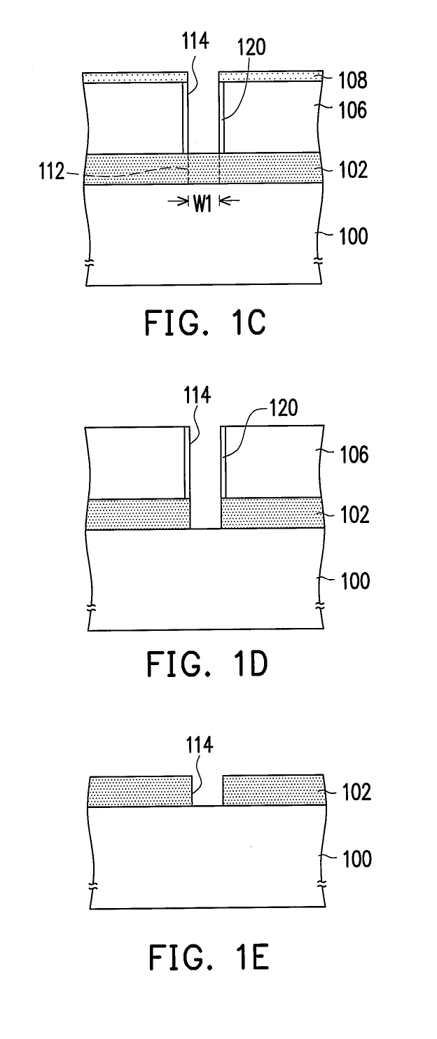

FIGS. 1A to 1E are schematic cross-sectional views illustrating a patterning method according to one embodiment of the present invention.

Referring to FIG. 1A, a substrate 100 is provided, and a material layer 102 has already been formed thereon. An opening pattern 112 is about to be formed in the material layer 102, and the predetermined width of the opening pattern 112 is W1. First, an underlying layer 106, a silicon rich organic layer 108, and a photoresist layer 110 are formed on the material layer 102 in succession.

The photoresist layer 110 is made of a positive or a negative photoresist, which can be a photoresist material (e.g. a 193 nm photoresist material) generally adopted in a conventional photolithographic process. Alternatively, the material of photoresist layer can also be a waterproof photoresist layer applied in an immersion lithography process, or a photoresist material layer covered by a waterproof layer. The thickness of the photoresist layer 110 is approximately 500˜2000 angstrom, for example. The silicon rich organic layer 108 is made of an organic silicon material adopted in a bottom anti-reflection coating (BARC) layer, for example, a silicon polymer containing 5-30 wt. % of silicon, as disclosed in the U.S. Pat. No. 6,025,117. The content of said patent should be incorporated herein for reference. The silicon rich organic layer 108 is, for example, formed by a spinning coating method, and the thickness thereof is approximately 250˜500 angstrom, for example. The material of the underlying layer 106 includes a novolak resin, for example, an I-line photoresist layer, and the thickness thereof is approximately 1000˜2500 angstrom, for example.

Referring to FIG. 1B, the photoresist layer 110 is patterned so as to form an opening pattern 114 therein. The method of patterning the photoresist layer 110 includes performing a conventional photolithographic process or an immersion lithography process to achieve an exposure. Then, the opening pattern 114 is formed through a development process.

From the observation conducted after development inspection (ADI) is performed, given that the opening pattern 114 in the photoresist layer 110 is found not able to form an opening with a predetermined width W1 consistent with that of the opening 112 in the successive process, a trimming process for modifying the width of the opening can be performed prior to etching the silicon rich organic layer 108, so that the width of the opening pattern 114 is appropriate.

Thereafter, the photoresist layer 110 is adopted as a mask to etch the silicon rich organic layer 108, so as to transfer the opening pattern 114 to the silicon rich organic layer 108. The etching method is, for example, a dry etching process. During the etching process, the photoresist layer 110 is consumed due to the etching effect. When the opening pattern 114 is completely transferred to the silicon rich organic layer 108, the photoresist layer 110 is thoroughly consumed, or a small part thereof still remains on the silicon rich organic layer 108.

Next, referring to FIG. 1C, using the photoresist layer 110 and the silicon rich organic layer 108 as masks, the underlying layer 106 is etched, so as to transfer the opening pattern 114 to the underlying layer 106. After the underlying layer 106 is completely patterned, the photoresist layer 110 on the silicon rich organic layer 108 has already been consumed thoroughly. The method of etching the underlying layer 106 includes an anisotropic etching process, for example, a dry etching process. The reactive gas adopted in the etching process includes a passivation gas, an etching gas, and a carrier gas. The passivation gas is, for example, SiCl₄ or SO₂, and the content of the passivation gas is 0.5%˜60% of the total amount of the reactive gas. When the passivation gas is SO₂, the content of SO₂ is preferably 30%˜60% of the total amount of the reactive gas. On the other hand, when the passivation gas is SiCl₄, the content of the SiCl₄ is preferably 0.5%˜2% of the total amount of the reactive gas. The etching gas is selected from a group consisting of O₂, NF₃, fluorinated hydrocarbon compound, and the combination thereof. The fluorinated hydrocarbon compound is selected from a group consisting of CF₄, CHF₃, CH₂F₂, CH₃F, and the combination thereof. The carrier gas is selected from a group consisting of He, Ar, N₂, and the combination thereof. During the etching process, the passivation gas can form a passivation layer 120 at side walls of the underlying layer which has been etched, so as to prevent the damage caused by the etching gas and keep the pattern as shaped. When the passivation gas is SO₂, the passivation layer 120 formed thereby may be polymer. On the contrary, the passivation layer 120 formed thereby may be silicon oxide when the passivation gas is SiCl₄. In one embodiment, the process of etching the underlying layer 106 is performed at the temperature between 15° C. and 70° C., the operating pressure ranges from 3 mT to 100 mT, and the bias is from 0 watt to 60 watt.

Next, referring to FIG. 1D, using the silicon rich organic layer 108 as a mask, the material layer 102 is etched, so as to transfer the opening pattern 114 to the material layer 102. After the opening pattern 114 is completely transferred to the material layer 102, the silicon rich organic layer 108 has already been consumed thoroughly. During the etching process, given that the silicon rich organic layer 108 has been consumed thoroughly, the underlying layer 106 can be adopted as an etching mask to perform the etching process continuously until the opening pattern 114 is thoroughly transferred to the material layer 102. The method of etching the material layer 102 is, for example, a dry etching process. The etching gas varies according to the material layer 102 to be etched.

Then, referring to FIG. 1E, the underlying layer 106 is removed. The method of removing the underlying layer 106 can be a dry removing process or a wet removing process.

Said patterning method can be applied to form a contact opening, a via opening, or a trench. Namely, said material layer 102 is, for example, composed of silicon oxide, low dielectric constant material with a dielectric constant lower than 4, or a porous material layer. The opening pattern 112 which is about to be formed in the material layer 102 is, for example, the contact opening, the via opening, or the trench. When the pattern 114 in the photoresist layer 110 is transferred from the silicon rich organic layer 108 and the underlying layer 106 to the dielectric layer 102, the contact opening, the via opening, or the trench can then be formed in the dielectric layer.

Said patterning method can be applied not only to form the contact opening, the via opening, or the trench, but also to form a gate structure and a shallow trench isolation (STI) structure. A preferred embodiment accompanied with figures is described in detail below.

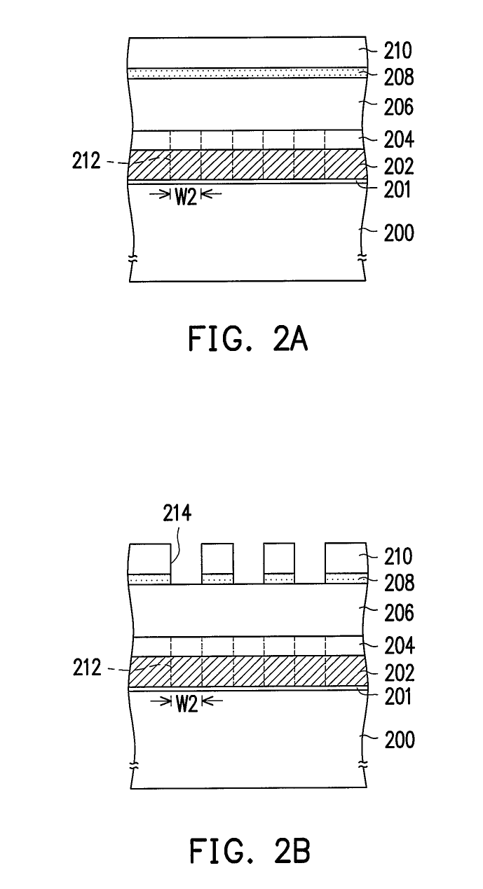

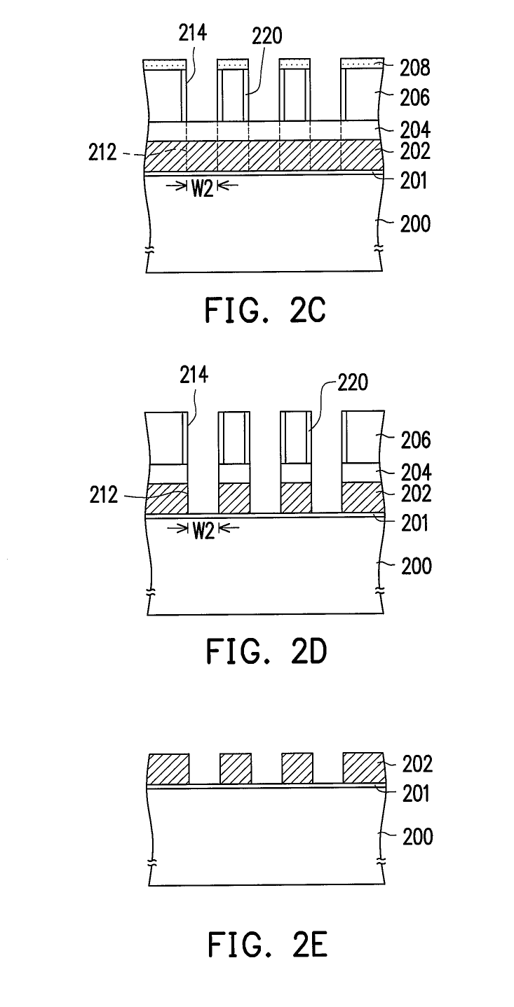

FIGS. 2A to 2E are schematic cross-sectional views illustrating the steps of fabricating a gate structure according to another embodiment of the present invention.

Referring to FIG. 2A, a substrate 200 is provided, wherein a gate dielectric layer 201 and a gate conductive layer 202 have already been formed thereon. A space 212 with a predetermined width as W2 is about to be formed in the gate conductive layer 202. The gate conductive layer 202 is made of a doped polysilicon layer, or a polycide metal layer consisting of a doped polysilicon layer and a silicide layer, for example. In one embodiment, the gate conductive layer 202 may further cover a mask layer 204 which is made of, for example, silicon oxide or silicon nitride. Next, an underlying layer 206, a silicon rich organic layer 208, and a photoresist layer 210 are formed on the substrate 200 in succession. The photoresist layer 210 is made of a positive or a negative photoresist, for example, a 193 nm photoresist material, and the thickness thereof is approximately 500˜2000 angstrom. The silicon rich organic layer 208 is, for example, made of a silicon polymer containing 5-30 wt. % of silicon, as disclosed in the U.S. Pat. No. 6,025,117. The thickness thereof is approximately 250˜500 angstrom. The material of the underlying layer 206 is, for example, an I-line photoresist layer. The thickness thereof is approximately 2000˜2500 angstrom, for example. In one embodiment, the thickness of the photoresist layer is 1200 angstrom; that of the silicon rich organic layer 208 is 300 angstrom; that of the underlying layer 206 is 1500 angstrom; that of the mask layer is 550 angstrom; that of the gate conductive layer 202 is 800 angstrom, and that of the gate dielectric layer 201 is 12 angstrom.

Referring to FIG. 2B, the photoresist layer 210 is patterned to form an opening pattern 214 therein. The method of patterning the photoresist layer 210 includes performing a conventional photolithographic process or an immersion lithography process to achieve an exposure. Then, the opening pattern 214 is formed through a development process.

From the observation conducted after the development inspection is performed, given that the opening pattern 214 in the photoresist layer 210 cannot form a space with a predetermined width W2 consistent with that of the space 212 in the successive process, a trimming process for modifying the width of the space can be performed before etching the silicon rich organic layer 208, so that the width of the opening pattern 214 is appropriate. As reactive gases, CF₄ and hydrogen bromide (HBr) can be employed in the trimming process, so as to etch the photoresist layer 210.

Thereafter, using the photoresist layer 210 as a mask, the silicon rich organic layer 208 is etched, so as to transfer the opening pattern 214 to the silicon rich organic layer 208. The etching method is, for example, a dry etching process. The etching gas can be a fluorine-bearing gas, for example, perfluoride compound.

Next, referring to FIG. 2C, using the photoresist layer 210 and the silicon rich organic layer 208 as masks, the underlying layer 206 is etched, so as to transfer the opening pattern 214 to the underlying layer 206. After the underlying layer 206 is completely patterned, the photoresist layer 210 on the silicon rich organic layer 208 has already been consumed thoroughly. The etching method can be an anisotropic etching process, for example, a dry etching process. The reactive gas adopted in the etching process includes a passivation gas, an etching gas, and a carrier gas. The passivation gas is, for example, SiCl₄ or SO₂, and the content of the passivation gas is 0.5%˜60% of the total amount of the reactive gas. When the passivation gas is SO₂, the content of SO₂ is preferably 30%˜60% of the total amount of the reactive gas. On the other hand, when the passivation gas is SiCl₄, the content of the SiCl₄ is preferably 0.5%˜2% of the total amount of the reactive gas. The etching gas is selected from a group consisting of O₂, NF₃, fluorinated hydrocarbon compound, and the combination thereof. The fluorinated hydrocarbon compound is selected from a group consisting of CF₄, CHF₃, CH₂F₂, CH₃F, and the combination thereof. The carrier gas is selected from a group consisting of He, Ar, N₂, and the combination thereof. During the etching process, the passivation gas can form a passivation layer 220 at side walls of the underlying layer which has been etched, so as to prevent the damage caused by the etching gas and keep the pattern as shaped.

Next, referring to FIG. 2D, with the silicon rich organic layer 208 as a mask, the mask layer 204 and the conductive layer 202 are etched, so as to transfer the opening pattern 214 to the mask layer 204 and the conductive layer 202. After the opening pattern 214 is completely transferred to the conductive layer 202, the silicon rich organic layer 208 has already been consumed thoroughly. Given that the silicon rich organic layer 208 has been thoroughly consumed during the etching process, the underlying layer 206 can be adopted as an etching mask to perform the etching process continuously until the opening pattern 214 is completely transferred to the conductive layer 202. The method of etching the conductive layer 202 is, for example, a dry etching process. The etching gas is, for example, perfluorocarbons or SF₆.

Then, referring to FIG. 2E, the underlying layer 206 is removed, so as to expose the patterned conductive layer 202. The method of removing the underlying layer 206 can be a dry removing process, for example, an oxygen plasma ashing process. The mask layer 204 can be removed or serve as a cover layer.

Experiment

An underlying layer, a silicon rich organic layer, and a photoresist layer are formed on the polysilicon layer in succession. Then, the method of the present invention is adopted to transfer the pattern. When the etching process is performed on the underlying layer, SO₂/O₂/He serve as reactive gases. The critical dimensions (nm) after performing the patterning in each step are shown in Table 1.

TABLE 1

| | Photoresist | Silicon Rich | Underlying | Polysilicon | | |
|---|---|---|---|---|---|---|
| | layer | Organic Layer | layer | Layer | CD bias | Loading |
| Dense | 68 | 60 | 61 | 47 | −21 | −1 |
| Region | | | | | | |
| Sparse | 69 | 66 | 71 | 47 | −22 | |
| Region | | | | | | |

According to the experiment results indicated above, after the underlying layer is etched, the dimension of the pattern formed thereby is slightly larger than that by the silicon rich layer. Hence, a passivation layer is deductively formed at side walls of the patterned underlying layer. Moreover, the loading displayed in the dense region and the sparse region is merely 1 nm, proving that the method disclosed in the present invention can indeed overcome the loading in both the dense and the sparse regions. Additionally, the CDs of the patterns respectively formed in said regions are quite similar.

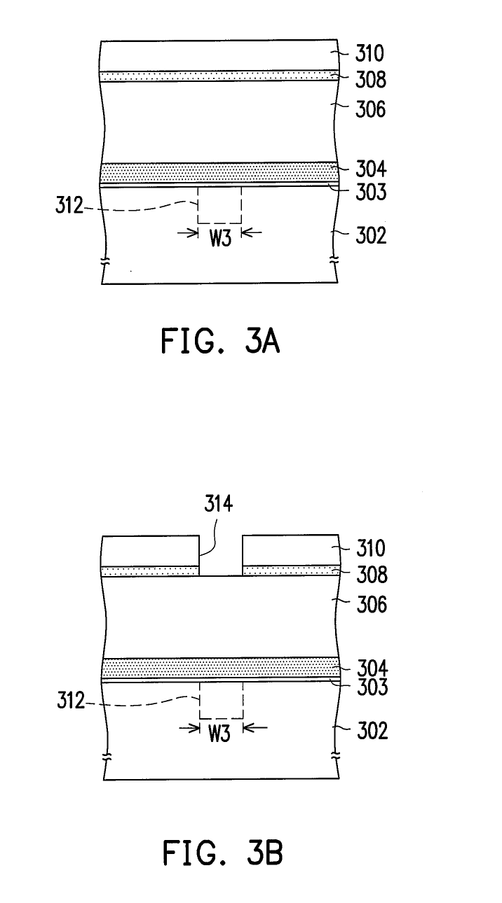

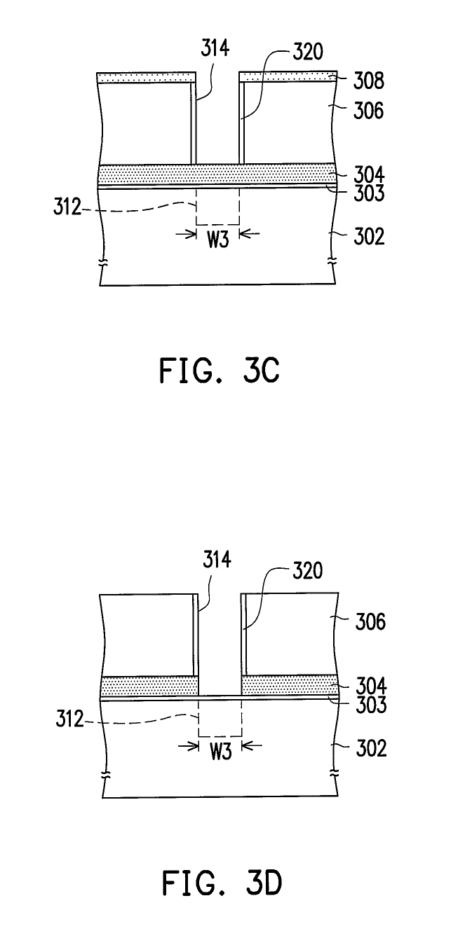

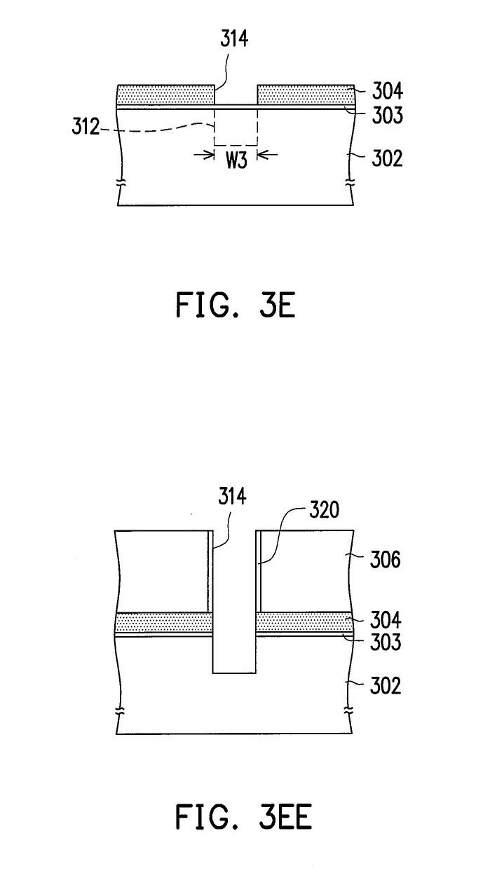

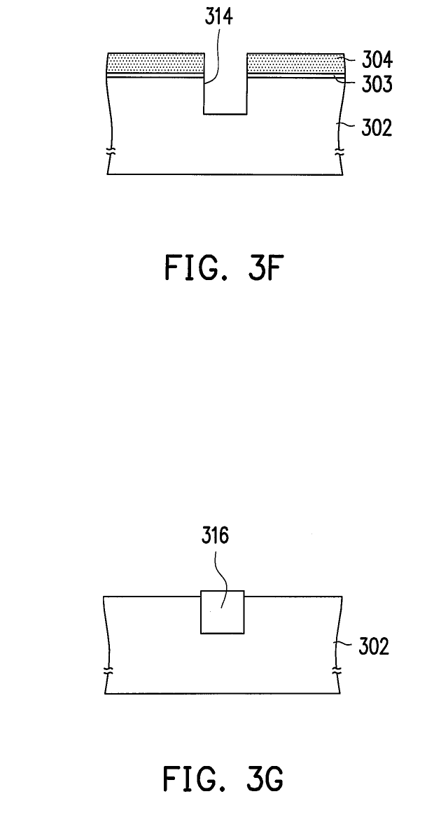

FIGS. 3A to 3G are schematic cross-sectional views illustrating the steps of fabricating a shallow trench isolation (STI) structure according to still another embodiment of this invention.

Referring to FIG. 3A, a substrate 302 is provided, and a trench 312 is about to be formed in the substrate 302. The predetermined width of the trench 312 is W3. The substrate 302 is, for example, made of a semiconductor bulk, e.g. silicon, germanium, silicon germanium, or silicon carbide, or silicon on an insulating layer (SOI). Thereafter, a pad oxide layer 303, a mask layer 304, an underlying layer 306, a silicon rich organic layer 308, and a photoresist layer 310 are formed on the substrate 302.

The photoresist layer 310 is made of a positive or a negative photoresist, for example, a 193 nm photoresist material. The thickness thereof is approximately from 500 to 2000 angstrom. The silicon rich organic layer 308 can be made of an organic silicon material used in a bottom anti-reflection coating (BARC) layer, for example, a silicon polymer containing 5-30 wt. % of silicon, as disclosed in the U.S. Pat. No. 6,025,117. The content of said patent should be incorporated herein for reference. The thickness of said silicon rich organic layer is approximately 250˜500 angstrom. The material of the underlying layer 306 is, for example, an I-line photoresist layer, and the thickness thereof is approximately 1000˜2500 angstrom. The mask layer 304 is, for example, made of silicon nitride, and the method of fabricating the same can be a chemical vapor deposition method. The thickness thereof is slightly larger than that of the silicon rich organic layer 308, approximately ranging from 250 to 900 angstrom, for example.

Referring to FIG. 3B, the photoresist layer 310 is patterned, so as to form a trench pattern 314 therein. The method of patterning the photoresist layer 310 includes performing a conventional photolithographic process or an immersion lithography process to achieve an exposure. Then, the trench pattern 314 is formed through a development process.

From the observation conducted after the development inspection is performed, given that the trench pattern 314 in the photoresist layer 310 is found not able to form a trench with a predetermined width W3 consistent with that of the trench 312 in the successive process, a trimming process for modifying the width of the trench can be performed before etching the silicon rich organic layer 308, so that the width of the trench pattern 314 is appropriate. As reactive gases, CF₄ and hydrogen bromide (HBr) can be employed in the trimming process.

Thereafter, using the photoresist layer 310 as a mask, the silicon rich organic layer 308 is etched, so as to transfer the trench pattern 314 to the silicon rich organic layer 308. The etching method is, for example, a dry etching method. The etching gas can be a fluorine-bearing gas, for example, perfluoride compound. During the etching process, the photoresist layer 310 is consumed due to the etching effect. Accordingly, when the trench pattern 314 is completely transferred to the silicon rich organic layer 308, a small part of the photoresist layer 310 may still remain on the silicon rich organic layer 308, or the photoresist layer 310 is thoroughly consumed.

Next, referring to FIG. 3C, using the photoresist layer 310 and the silicon rich layer 308 as hard masks, the underlying layer 306 is etched, so as to transfer the trench pattern 314 to the underlying layer 306. After the underlying layer 306 is completely patterned, the photoresist layer 310 on the silicon rich organic layer 308 has already been consumed thoroughly. The etching method can be an anisotropic etching process, for example, a dry etching process. The reactive gas adopted in the etching process includes a passivation gas, an etching gas, and a carrier gas. The passivation gas is, for example, SO₂ or SiCl₄, the content of the passivation gas is 0.5%˜60% of the total amount of the reactive gas. When the passivation gas is SO₂, the content of SO₂ is 30%˜60% of the total amount of the reactive gas. In addition, when the passivation gas is SiCl₄, the content of SiCl₄ is 0.5%˜2% of the total amount of the reactive gas. The etching gas is selected from a group consisting of O₂, NF₃, fluorinated hydrocarbon compound, and the combination thereof. The fluorinated hydrocarbon compound is selected from a group consisting of CF₄, CHF₃, CH₂F₂, CH₃F, and the combination thereof. The carrier gas is selected from a group consisting of He, Ar, N₂, and the combination thereof. During the etching process, the passivation gas can form a passivation layer 320 at side walls of the underlying layer which has been etched, so as to prevent the damage caused by the etching gas and keep the pattern as shaped.

Next, referring to FIG. 3D, using the silicon rich organic layer 308 and the underlying layer 306 as masks, the mask layer 304 is etched, so as to transfer the trench pattern 314 to the mask layer 304. During the etching process, an etchant resulting in a similar etching rate to that of the silicon rich organic layer 308 and of the mask layer 304 can be selected to perform said etching process. The silicon rich organic layer 308 is thinner than the mask layer 304. Hence, when the trench pattern 314 is completely transferred to the mask layer 304, the silicon rich organic layer 308 has been consumed thoroughly with no residues remaining on the underlying layer 306.

After the etching process is performed on the mask layer 304, and the trench pattern 314 in the mask layer 304 is found unable to form a trench with a predetermined width W3 consistent with that of the trench 312 in the successive process, a trimming process for modifying the width of the trench can be performed before etching the substrate 302, so that the width of the trench pattern 314 is appropriate. During the trimming process, the underlying layer 306 and the mask layer 304 must be removed at a roughly equivalent rate, so as to ensure the consistency between the trench patterns 314 formed in both layers. As etching gases, CF₄ or CHF₃ can be employed to perform the etching function for completing the trimming process.

Thereafter, as shown in FIG. 3E, the underlying layer 306 is removed. The method of removing the underlying layer 304 can be a dry removing process or a wet removing process. The dry removing process is, for example, an oxygen plasma ashing process. Next, using the mask layer 304 as a mask, the pad oxide layer 303 and the substrate 302 are etched, so as to transfer the trench pattern 314 to the substrate 302, as shown in FIG. 4F. The method of etching the substrate 302 is a dry etching process, for example.

Alternatively, referring to FIG. 3EE, after the trench pattern 314 has been completely transferred to the mask layer 304, the underlying layer 306 can be adopted as a mask without being removed to etch the substrate 302, so as to transfer the opening pattern 314 to the substrate 302 and form the trench. During the etching process, given that the underlying layer 306 is consumed thoroughly, the mask layer 304 can be adopted as a mask to perform the etching process continuously until the trench pattern 314 has been thoroughly transferred to the substrate 302. During the etching process, given that the underlying layer 306 is not completely consumed, the underlying layer 306 is removed after the trench pattern 314 has been thoroughly transferred to the substrate 302, as shown in FIG. 3F.

Subsequently, referring to FIG. 3G, an insulating layer 316 is formed in the trench 314. The method of forming the insulating layer 316 includes forming an insulating material (e.g. silicon oxide) on the substrate 302. Thereafter, using the mask layer 304 as a stop layer, unnecessary insulating material is removed. The method of removing unnecessary insulating material is, for example, an etching back process or a chemical-mechanical polishing process. Next, the mask layer 304 and the pad oxide layer 303 are removed, and thereby the fabrication of the shallow trench isolation (STI) structure is accomplished.

In the patterning method disclosed in the present invention, the passivation gas is applied in the process of etching the underlying layer. Thereby, the passivation layer can be formed in the etched part of the underlying layer, so as to ultimately reduce the CD loss of the target layer, to modify the tilt patterns, and to diminish the isolate dense loading effect.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A patterning method, comprising the steps of:
forming an underlying layer, a silicon rich organic layer, and a photoresist layer successively on a material layer;
patterning the photoresist layer;
patterning the silicon rich organic layer adopting the photoresist layer as a mask;
performing an etching process to pattern the underlying layer adopting the photoresist layer and the silicon rich organic layer as masks, wherein reactive gases employed during the etching process include a passivation gas, an etching gas, and a carrier gas;
patterning the material layer to form an opening adopting the silicon rich organic layer and the underlying layer as masks; and
removing the underlying layer.

2. The patterning method of claim 1, wherein the passivation gas includes SO₂ or SiCl₄.

3. The patterning method of claim 2, wherein the passivation gas is SO₂ and the content of SO₂ is 30% to 60% of the total amount of the reactive gas.

4. The patterning method of claim 2, wherein the passivation gas is SiCl₄ and the content of SiCl₄ is 0.5% to 2% of the total amount of the reactive gas.

5. The patterning method of claim 1, wherein the etching gas is selected from a group consisting of O₂, NF₃, fluorinated hydrocarbon compound, and the combination thereof.

6. The patterning method of claim 1, wherein the fluorinated hydrocarbon compound is selected from a group consisting of CF₄, CHF₃, CH₂F₂, CH₃F, and the combination thereof.

7. The patterning method of claim 1, wherein the carrier gas is selected from a group consisting of He, Ar, N₂, and the combination thereof.

8. The patterning method of claim 1, wherein the content of the passivation gas is 0.5% to 60% of the total amount of the reactive gas.

9. The patterning method of claim 1, wherein the material of the silicon rich organic layer includes organic silicon polymer comprising 5-30 wt. % of silicon.

10. The patterning method of claim 1, further comprising a trimming process after patterning the photoresist layer and before patterning the silicon rich organic layer to change the pattern in the photoresist layer.

11. The patterning method of claim 1, wherein the material of the underlying layer includes a novolak resin.

12. The patterning method of claim 1, wherein the material of the underlying layer includes an I-line photoresist layer.

13. The patterning method of claim 1, wherein the method of patterning the photoresist layer includes achieving an exposure through an immersion lithography process, and the photoresist layer is a waterproof photoresist layer or a photoresist material layer covered by a waterproof layer.

14. A method of forming a contact opening, a via opening, and/or a trench according to the patterning method of claim 1, wherein the material layer is a dielectric layer, and the opening formed thereby is a contact opening, a via opening, and/or a trench.

15. A method of forming a gate structure according to the patterning method of claim 1, wherein the material layer successively includes a gate dielectric layer, a gate conductive layer, and a mask layer from the bottom to the top, and the opening is a space within the gate structure.

16. A method of forming a shallow trench isolation structure according to the patterning method of claim 1, wherein the material layer includes a substrate and a mask layer from the bottom to the top, the opening is a trench, and the method further comprising:
forming an insulating layer in the trench; and
removing the mask layer.
